(19) United States
(12) Patent Application Publication
(10) Pub. No.: US 2026/0068588 A1
(43) Pub. Date: Mar. 5, 2026

(54) TRANSFER MODULE, TRANSFER CHAMBER, AND SUBSTRATE PROCESSING APPARATUS

(71) Applicant: SEMES CO., LTD., Cheonan-si (KR)

(72) Inventors: Ki Won HAN, Cheonan-si (KR); Hee Chan KIM, Cheonan-si (KR); Doo Hyun BAEK, Cheonan-si (KR); Sang Oh KIM, Cheonan-si (KR)

(73) Assignee: SEMES CO., LTD., Cheonan-si (KR)

(21) Appl. No.: 19/196,419

(22) Filed: May 1, 2025

(30) Foreign Application Priority Data
Aug. 29, 2024 (KR) 10-2024-0116961

(51) Int. Cl. H01L 21/677; H01L 21/67; H01L 21/687

(52) U.S. Cl. CPC H01L 21/67706

(57) ABSTRACT

Proposed are a transfer module that can exhaust air without scattering particles, and a transfer chamber and a substrate processing apparatus including the transfer module. The transfer module that transfers a substrate in the substrate processing apparatus includes a vertical gantry member configured to extend in a vertical direction, a horizontal gantry member coupled to the vertical gantry member to move in the vertical direction and configured to extend along a first horizontal direction perpendicular to the vertical direction, a horizontal driving member coupled to the horizontal gantry member and configured to move along the first horizontal direction, and a substrate transfer robot coupled to the horizontal driving member and driven in a second horizontal direction perpendicular to the first horizontal direction and a rotation direction.

### CROSS REFERENCE TO RELATED APPLICATION

The present application claims priority to Korean Patent Application No. 10-2024-0116961, filed Aug. 29, 2024, the entire contents of which are incorporated herein for all purposes by this reference.

### BACKGROUND

### 1. Field

The present disclosure relates to a transfer module for transferring a substrate, and a transfer chamber and a substrate processing apparatus including the transfer module.

### 2. Description of the Related Art

Semiconductor (or display) manufacturing is a process of manufacturing semiconductor devices on a substrate (e.g., wafer), and includes, for example, exposure, deposition, etching, ion implantation, cleaning, etc. In order to perform each manufacturing process, semiconductor manufacturing equipment for performing individual processes is provided in cleanrooms of a semiconductor manufacturing plant so that a process is performed on a substrate put into the semiconductor manufacturing equipment.

A transfer module is provided to transfer substrates between individual modules in the semiconductor manufacturing equipment. The transfer module consists of mechanisms that move along a plurality of driving axes. During the operation of the transfer module, fine particles are continuously generated, and the particles not only impede the operation of the transfer module but may also contaminate a substrate. Thus, an exhaust module for discharging particles to the outside is installed in the transfer module.

In a typical transfer module, an exhaust module is installed on one side of the transfer module and is configured to discharge air circulated along the internal space to the outside. For example, the structure is such that air circulated along the X-axis, Y-axis, Z-axis, and TH-axis (rotation axis) driving parts is discharged through the exhaust module. However, when air is discharged through such a circulation path, as the structure of the transfer module becomes complex, air is discharged at high pressure to ensure smooth discharge. The problem is that, if the air discharge pressure increases, particles may scatter inside a transfer chamber.

### SUMMARY

Accordingly, the present disclosure has been made keeping in mind the above problems occurring in the related art, and an objective of the present disclosure is to provide a transfer module that can exhaust air without scattering particles, and a transfer chamber and a substrate processing apparatus including the transfer module.

A transfer module for transferring a substrate in a substrate processing apparatus according to the present disclosure includes: a vertical gantry member configured to extend in a vertical direction; a horizontal gantry member coupled to the vertical gantry member to move in the vertical direction and configured to extend along a first horizontal direction perpendicular to the vertical direction; a horizontal driving member coupled to the horizontal gantry member and configured to move along the first horizontal direction; and a substrate transfer robot coupled to the horizontal driving member and driven in a second horizontal direction perpendicular to the first horizontal direction and a rotation direction, wherein a first exhaust module may be provided in the vertical gantry member, a second exhaust module may be provided on the horizontal gantry member, and a third exhaust module may be provided on the horizontal driving member, and the second exhaust module and the third exhaust module may be configured to discharge air toward the second horizontal direction.

In an embodiment of the present disclosure, the first exhaust module may be provided at a lower end of the vertical gantry member and may discharge air in a direction below a floor surface.

In an embodiment of the present disclosure, the second exhaust module may be provided in a pair, one of which may be installed at each end of the horizontal gantry member to exhaust air in the second horizontal direction.

In an embodiment of the present disclosure, the second exhaust modules may each operate independently.

In an embodiment of the present disclosure, the third exhaust module may be installed on a front side of the horizontal driving member facing the second horizontal direction and may discharge air in the second horizontal direction.

In an embodiment of the present disclosure, the first exhaust module, the pair of second exhaust modules, and the third exhaust module may each operate independently.

In an embodiment of the present disclosure, the first exhaust module, the pair of second exhaust modules, and the third exhaust module may each include a fan unit that generates airflow for exhausting air and a filter positioned in a direction of exhaust of air by the fan unit.

In an embodiment of the present disclosure, a negative pressure may be formed inside the vertical gantry member, the horizontal gantry member, and the horizontal driving member.

In an embodiment of the present disclosure, an exhaust fan may be positioned opposite the second exhaust module and the third exhaust module on a side wall of a transfer chamber where the transfer module is positioned.

A transfer chamber provided for transferring a substrate to a process chamber in a substrate processing apparatus according to the present disclosure may include: a substrate transfer module configured to transfer the substrate; and an exhaust fan configured to exhaust air discharged from the transfer module to outside.

A substrate processing apparatus according to the present disclosure may include: a load port module configured to have a stand on which a cassette containing a substrate is placed; an index module configured to have an index robot for transferring a substrate with respect to the cassette; a transfer module configured to receive a substrate from the index module and transfer the substrate to a process chamber where a process on the substrate is performed; and a processing module in which one or more process chambers are arranged.

According to the present disclosure, by providing an exhaust module for each driving axis of a transfer module, an air discharge path is simplified and air can be discharged more smoothly.

### BRIEF DESCRIPTION OF THE DRAWINGS

FIG. 1 shows the schematic structure of a substrate processing apparatus according to the present disclosure.

FIG. 2 shows the structures of an index module and a transfer module in the substrate processing apparatus.

FIG. 3 shows the structures of the transfer module and an exhaust module according to the present disclosure.

FIG. 4 shows cross sections of a horizontal gantry member and a horizontal driving member in the transfer module.

FIG. 5 shows the air exhaust process by the exhaust module in the transfer module according to the present disclosure.

FIG. 6 shows the structure of the transfer module viewed from the side.

FIGS. 7A and 7B show a fan unit and a filter of the exhaust module.

### DETAILED DESCRIPTION OF EXEMPLARY EMBODIMENTS

Hereinafter, with reference to the accompanying drawings, embodiments of the present disclosure will be described in detail so that those skilled in the art may easily carry out the present disclosure. The present disclosure may be embodied in many different forms and is not limited to the embodiments set forth herein.

In order to clearly describe the present disclosure, parts irrelevant to the description are omitted, and the same reference numerals are assigned to the same or similar components throughout the specification.

In addition, in various embodiments, components having the same configuration will be described only in representative embodiments by using the same reference numerals, and in other embodiments, only configurations different from the representative embodiments will be described.

Throughout the specification, when a part is said to be “connected (or coupled)” to another part, this includes not only the case of being “directly connected (or coupled)” but also “indirectly connected (or coupled)” with another member in between. In addition, when a part “includes”, “has”, or “comprises” a certain part, this means that other components may be further included without excluding other components unless otherwise stated.

Unless otherwise defined, all terms used herein, including technical or scientific terms, have the same meaning as commonly understood by a person skilled in the art. Terms such as those defined in the commonly used dictionaries should be construed as having meanings consistent with the meanings in the context of the related art and shall not be construed in ideal or excessively formal meanings unless expressly defined in this application.

As semiconductor manufacturing equipment, a substrate processing apparatus 1 of the present embodiment can be used to perform a process on a substrate such as a semiconductor wafer or a flat panel display panel. In particular, the substrate processing apparatus 1 of the present disclosure is a device that performs a liquid treatment on a substrate, for example, cleaning, coating, or developing.

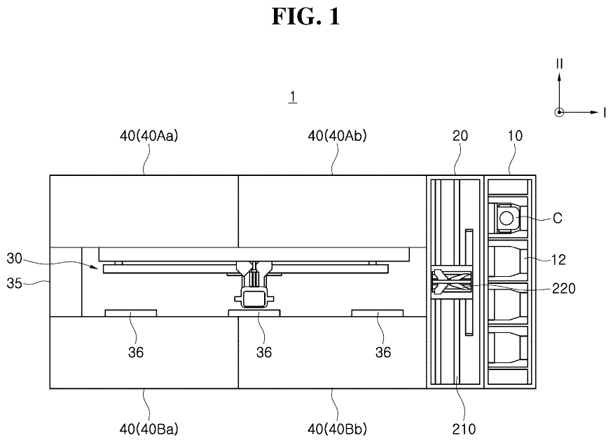

FIG. 1 shows the schematic structure of the substrate processing apparatus 1 according to the present disclosure. The substrate processing apparatus 1 is provided to perform a processing process on an input substrate and to take out the processed substrate. The substrate processing apparatus 1 includes a load port module 10, an index module 20, a transfer module 30, and a processing module 40. The substrate processing apparatus 1 may have an elongated shape in a first horizontal direction I. In this document, the first horizontal direction I represents the direction in which the transfer module 30 extends. A second horizontal direction II is a direction perpendicular to the first horizontal direction I. A vertical direction III represents a direction perpendicular to both the first horizontal direction I and the second horizontal direction II.

The load port module 10 is placed on one side of the substrate processing apparatus 1 and exposed to be accessible from the outside. As shown in FIG. 1, in the substrate processing apparatus 1, the load port module 10 has a stand 12 on which a cassette C containing a substrate is placed. The stand 12 may be arranged in plural numbers along the second horizontal direction II. Four stands 12 may be arranged along the second horizontal direction II. The cassette C is a container that accommodates substrates, and a plurality of substrates may be accommodated in one cassette C. The cassette C may be a front opening unified pod (FOUP) that can be opened on one side. When the cassette C is placed on the stand 12, the door of the cassette C is opened by an opener (not shown) of the load port module 10, so that a substrate can be taken out. In addition, a processed substrate may be stored in the cassette C.

The index module 20 is disposed between the load port module 10 and the transfer module 30 in the substrate processing apparatus 1. The index module 20 may withdraw a substrate from the cassette C located in the load port module 10 and then transfer the substrate to the transfer module 30. In addition, the index module 20 may receive a substrate from the transfer module 30 and store the substrate in the cassette C. The transfer module 30 includes an index rail 210 extending along the second horizontal direction II and an index robot 220 that moves along the index rail 210. The index robot 220 may take out a substrate from the cassette C while moving along the index rail 210 and then transfer the substrate to the transfer module 30. In addition, the index robot 220 may receive a substrate from the transfer module 30 and store the substrate in the cassette C.

The transfer module 30 may receive a substrate from the index module 20 and transfer the substrate to a process chamber where processing on a substrate is performed. The transfer module 30 may also pick up a substrate processed in the process chamber and deliver the substrate to the index module 20. The transfer module 30 may extend along the first horizontal direction I. Process chambers may be located on opposite sides of the transfer module 30. The transfer module 30 is located inside a transfer chamber 35. The transfer chamber 35 forms a space in which the transfer module 30 can be installed between the index module 20 and the processing module 40. The transfer chamber 35 includes the transfer module 30 and an exhaust fan 36 for discharging air discharged from the transfer module 30 to the outside. The transfer chamber 35 may further include electrical equipment for operation of the transfer module 30. An exhaust fan may also be installed on the ceiling of the transfer chamber 35, and an exhaust structure for discharging airflow may be installed on the floor surface of the transfer chamber 35.

The processing module 40 is composed of one or more process chambers. The processing module 40 may include process chambers arranged along the first horizontal direction I. In addition, the process chambers may be stacked in two or more stages in the vertical direction III. FIG. 1 shows an example in which four process chambers 40Aa, 40Ab, 40Ba, and 40Bb are arranged in the horizontal direction. When a substrate is input into each process chamber, liquid treatment is performed. The liquid-treated substrate may be taken out to the outside by the transfer module 30.

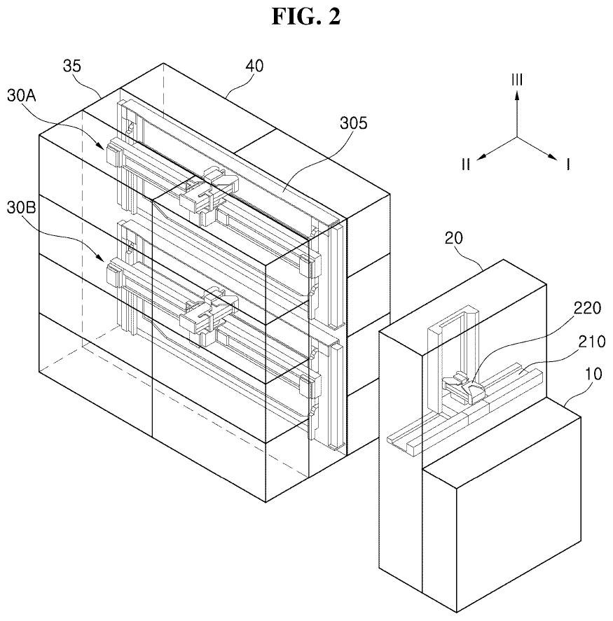

FIG. 2 shows the structures of the index module 20 and the transfer module 30 in the substrate processing apparatus 1. In FIG. 2, the structures of the load port module 10 and the processing module 40 are briefly expressed. As shown in FIG. 2, the transfer module 30 extends along the first horizontal direction I, and the index module 20 extends along the second horizontal direction II. The transfer module 30 and process chambers may be arranged in a stacked manner in the vertical direction III. Referring to the example of FIG. 2, transfer modules 30A and 30B may be stacked in two stages, and process chambers may be arranged in four stages. The upper transfer module 30A may transfer substrates to the upper first and second stage process chambers, and the lower transfer module 30B may transfer substrates to the lower first and second stage process chambers.

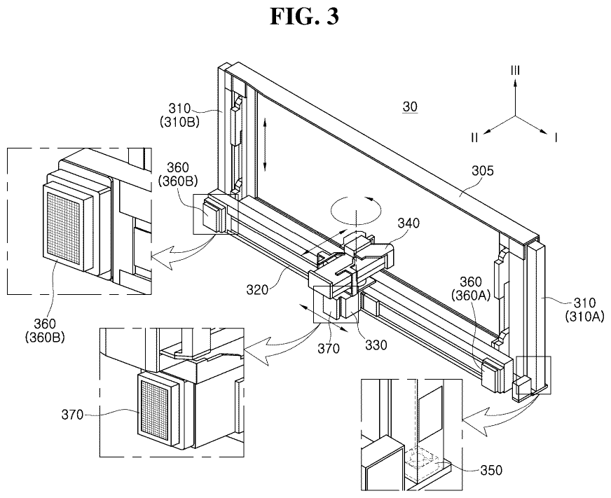

FIG. 3 shows the structure of the transfer module 30 according to the present disclosure. The transfer module 30 includes: a vertical gantry member 310 extending in the vertical direction III; a horizontal gantry member 320 coupled to the vertical gantry member 310 to move in the vertical direction III and extending along the first horizontal direction I perpendicular to the vertical direction III; a horizontal driving member 330 coupled to the horizontal gantry member 320 and moving along the first horizontal direction I; and a substrate transfer robot 340 driven along the horizontal driving member 330 in the second horizontal direction II perpendicular to the first horizontal direction I and a rotation direction.

The vertical gantry member 310 is a driving part erected in the vertical direction III at each end of the transfer module 30. The vertical gantry member 310 may be arranged side by side at each end of the transfer module 30. The vertical gantry member 310 is a structure fixed to each end of the transfer module 30. A vertical gantry member 310A on a first side and a vertical gantry member 310B on a second side may be fixed to be erected in the vertical direction III.

A first exhaust module 350 is provided in the vertical gantry member 310. Referring to FIG. 3, the first exhaust module 350 that exhausts air in the vertical direction III is provided at the lower part of the vertical gantry member 310. The first exhaust module 350 is provided at the lower end of the vertical gantry member 310 and may discharge air in a direction below the floor surface. The first exhaust module 350 may discharge air in the internal space of the vertical gantry member 310 through an exhaust port below the floor surface. The first exhaust module 350 may be located in the internal space of the vertical gantry member 310.

The horizontal gantry member 320 is a horizontal driving member extending along the first horizontal direction I. The horizontal gantry member 320 is coupled to the vertical gantry member 310. The horizontal gantry member 320 is coupled to the vertical gantry member 310 located on opposite sides and may be moved up and down in the vertical direction III. Vertical linear motors may be respectively coupled to opposite sides of the horizontal gantry member 320. The vertical linear motors installed on opposite sides of the horizontal gantry member 320 may operate in synchronization with each other. By operating the vertical linear motors in synchronization with each other, the horizontal gantry member 320 may be prevented from tilting to one side.

The horizontal gantry member 320 extends long along the first horizontal direction I and is configured not to be deformed despite the load of the horizontal driving member 330 and the substrate transfer robot 340. The horizontal gantry member 320 includes a base frame 322 extending along the first horizontal direction I. The base frame 322 extends in the first horizontal direction I and has a shape with one side open. In addition, the horizontal gantry member 320 includes a pair of linear guide rails 324 provided in the internal space of the base frame 322 along the first horizontal direction I. An upper linear guide rail 324A and a lower linear guide rail 324B may be spaced apart from each other with respect to the vertical direction III.

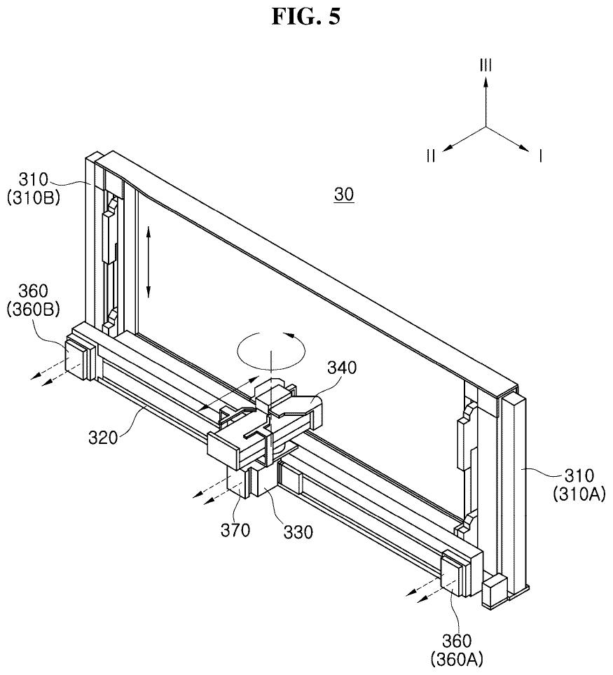

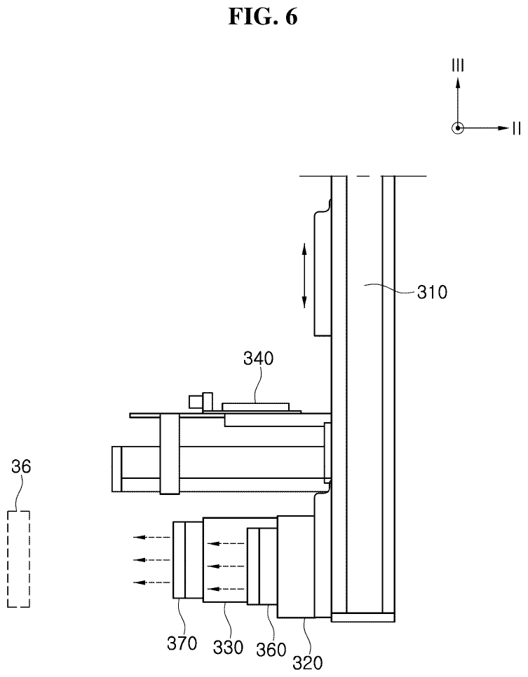

A second exhaust module 360 is provided on the horizontal gantry member 320. The second exhaust module 360 is provided in a pair, one of which is installed at each end of the horizontal gantry member 320, and exhausts air in the second horizontal direction II. Referring to FIG. 3, two second exhaust modules 360A and 360B may be provided at opposite ends of the horizontal gantry member 320. The pair of second exhaust modules 360A and 360B may operate independently. Compared to the conventional method in which air is circulated along a plurality of axes and then discharged, the exhaust module of the present disclosure is provided for each driving axis of the transfer module 30, and the plurality of exhaust modules operate independently to discharge air. The second exhaust module 360 may exhaust air toward the second horizontal direction II. The air discharged toward the second horizontal direction II may be discharged to the outside through the exhaust fan 36 provided on the side wall of the transfer chamber 35. Referring to FIGS. 5 and 6, the two second exhaust modules 360A and 360B at opposite ends of the horizontal gantry member 320 may operate independently and exhaust air inside the horizontal gantry member 320 to the outside.

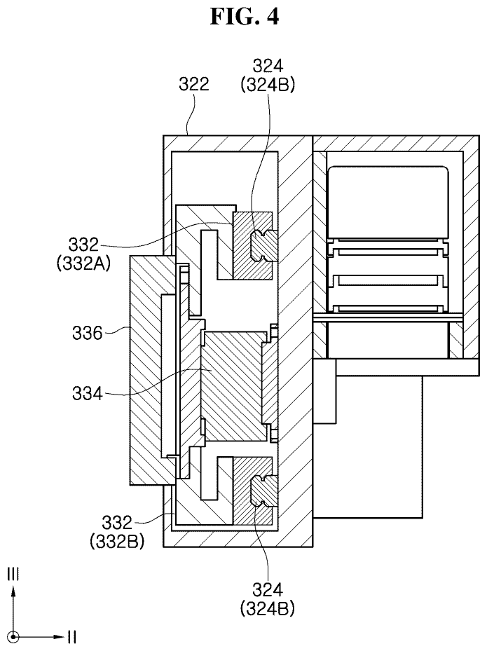

The horizontal driving member 330 is configured to move in the first horizontal direction I along the horizontal gantry member 320. Referring to FIG. 4, the horizontal driving member 330 includes: a linear guide 332 provided in the internal receiving space of the base frame 322 and extending along the first horizontal direction I; a linear motor 334 that generates power to move in the first horizontal direction I along the linear guide 332; and a horizontal driving body 336 that moves in the first horizontal direction I along the linear guide 332 by the power of the linear motor 334. The linear guide 332 is provided in a pair, and the linear guides 332 are arranged to be spaced apart along the vertical direction III in the internal space of the base frame 322. That is, an upper linear guide 332A and a lower linear guide 332B are arranged to be spaced apart from each other in the vertical direction III. The linear guide 332 is coupled to the linear guide rail 324 and may be moved. The upper linear guide 332A is coupled to the upper linear guide rail 324A, and the lower linear guide 332B is coupled to the lower guide rail 324B. The linear motor 334 is disposed between the linear guides 332A and 332B. The horizontal driving body 336 is a structure coupled to the linear motor 334 and is configured to move along the linear guide 332 in the first horizontal direction I.

Referring again to FIG. 3, a third exhaust module 370 is provided on the horizontal driving member 330. The third exhaust module 370 is installed on the front side of the horizontal driving member 330 facing the second horizontal direction II and discharges air in the second horizontal direction II. Referring to FIGS. 5 and 6, the third exhaust module 370 may discharge air in the second horizontal direction II in the same way as the second exhaust module 360. The third exhaust module 370 discharges air in the second horizontal direction II, and the exhaust fan 36 is positioned facing the third exhaust module 370 so that air can be discharged to the outside of the transfer chamber 35.

The substrate transfer robot 340 is coupled to the horizontal driving body 336 and may move along the first horizontal direction I with the horizontal driving body 336. The substrate transfer robot 340 may include a robot arm and a robot hand for handling the substrate. In addition, the substrate transfer robot 340 may move back and forth along the second horizontal direction II. In addition, the substrate transfer robot 340 may be driven to rotate.

According to the present disclosure, by applying a structure in which the horizontal gantry member 320 moves in the vertical direction III along the fixed vertical gantry member 310, the driving volume of the substrate transfer robot 340 may be reduced. Accordingly, the internal accessibility of the transfer module 30 is improved, airflow control is facilitated, and high-speed operation of the substrate transfer robot 340 may be realized.

In the present disclosure, the first exhaust module 350, the second exhaust module 360, and the third exhaust module 370 operate independently. The first exhaust module 350 installed on the vertical gantry member 310, the second exhaust module 360 installed on the horizontal gantry member 320, and the third exhaust module 370 installed on the horizontal driving member 330 each operate independently to discharge air, thereby enabling the air to be discharged smoothly.

Due to the first exhaust module 350, the second exhaust module 360, and the third exhaust module 370, a negative pressure is formed inside the vertical gantry member 310, the horizontal gantry member 320, and the horizontal driving member 330. Thus, particles existing around the transfer module 30 inside the transfer chamber 35 are sucked into the inside of the vertical gantry member 310, the horizontal gantry member 320, and the horizontal driving member 330 by the negative pressure, and air may be discharged to the outside by the first exhaust module 350, the second exhaust module 360, and the third exhaust module 370.

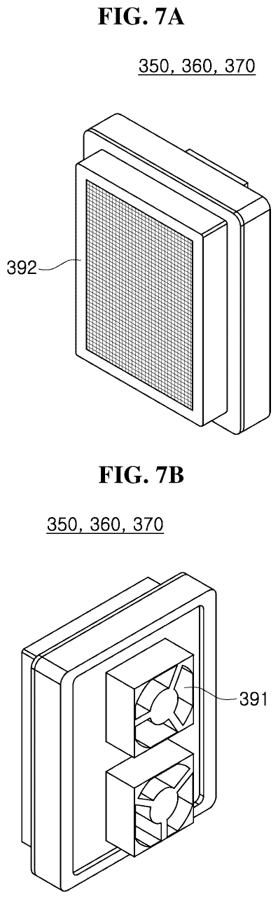

FIGS. 7A and 7B show a fan unit 391 and a filter 392 of the exhaust module 350, 360, or 370. FIG. 7A shows the filter 392 located on the outside of the exhaust module 350, 360, or 370, and FIG. 7B shows the fan unit 391 located on the inside of the exhaust module 350, 360, or 370. The first exhaust module 350, the second exhaust module 360, and the third exhaust module 370 each include the fan unit 391 that generates airflow for exhausting air and the filter 392 positioned in the direction of exhaust of air by the fan unit 391. The fan unit 391 is provided to discharge air to the outside while being located inside the exhaust module 350, 360, or 370, that is, in the internal space of the vertical gantry member 310, the horizontal gantry member 320, and the horizontal driving member 330. The filter 392 is located outside the exhaust module 350, 360, or 370, that is, outside of the vertical gantry member 310, the horizontal gantry member 320, and the horizontal driving member 330, and filters foreign substances from the air discharged outside.

According to the present disclosure, the exhaust fan 36 is located at a position opposite to the second exhaust module 360 and the third exhaust module 370 on the side wall of the transfer chamber 35 where the transfer module 30 is positioned. The exhaust fan 36 is provided on the side wall of the transfer chamber 35 to exhaust the internal air of the transfer chamber 35 to the outside. As shown in FIG. 6, the exhaust fan 36 is positioned opposite the second exhaust module 360 and the third exhaust module 370 in the transfer chamber 35. Thus, the air discharged in the second horizontal direction II by the second exhaust module 360 and the third exhaust module 370 may be again sucked into the exhaust fan 36 and discharged to the outside.

The present embodiments and drawings attached to this specification only clearly illustrate a part of the technical idea included in the present disclosure, and it is obvious that all modifications and specific embodiments that can be easily inferred by those skilled in the art within the scope of the technical idea included in the specification and drawings of the present disclosure are included in the scope of the rights of the present disclosure.

Therefore, the idea of the present disclosure should not be limited to the described embodiments, and not only the patent claims described below, but also all things that are equivalent or have equivalent modifications to these patent claims are considered to fall within the scope of the present disclosure.

What is claimed is:

1. A transfer module that transfers a substrate in a substrate processing apparatus, the module comprising:
a vertical gantry member configured to extend in a vertical direction;
a horizontal gantry member coupled to the vertical gantry member to move in the vertical direction and configured to extend along a first horizontal direction perpendicular to the vertical direction;
a horizontal driving member coupled to the horizontal gantry member and configured to move along the first horizontal direction; and
a substrate transfer robot coupled to the horizontal driving member and driven in a second horizontal direction perpendicular to the first horizontal direction and a rotation direction,
wherein a first exhaust module is provided in the vertical gantry member, a second exhaust module is provided on the horizontal gantry member, and a third exhaust module is provided on the horizontal driving member, and
wherein the second exhaust module and the third exhaust module are configured to discharge air toward the second horizontal direction.

2. The module of claim 1, wherein the first exhaust module is provided at a lower end of the vertical gantry member and discharges air in a direction below a floor surface.

3. The module of claim 1, wherein the second exhaust module is provided in a pair, one of which is installed at each end of the horizontal gantry member to exhaust air in the second horizontal direction.

4. The module of claim 3, wherein the second exhaust modules each operate independently.

5. The module of claim 1, wherein the third exhaust module is installed on a front side of the horizontal driving member facing the second horizontal direction and discharges air in the second horizontal direction.

6. The module of claim 1, wherein the first exhaust module, the pair of second exhaust modules, and the third exhaust module each operate independently.

7. The module of claim 1, wherein the first exhaust module, the pair of second exhaust modules, and the third exhaust module each include a fan unit that generates airflow for exhausting air and a filter positioned in a direction of exhaust of air by the fan unit.

8. The module of claim 1, wherein a negative pressure is formed inside the vertical gantry member, the horizontal gantry member, and the horizontal driving member.

9. The module of claim 1, wherein an exhaust fan is positioned opposite the second exhaust module and the third exhaust module on a side wall of a transfer chamber where the transfer module is positioned.

10. A transfer chamber provided for transferring a substrate to a process chamber in a substrate processing apparatus, the chamber comprising:
a substrate transfer module configured to transfer the substrate; and
an exhaust fan configured to exhaust air discharged from the transfer module to outside,
wherein the substrate transfer module comprises:
a vertical gantry member configured to extend in a vertical direction;
a horizontal gantry member coupled to the vertical gantry member to move in the vertical direction and configured to extend along a first horizontal direction perpendicular to the vertical direction;
a horizontal driving member coupled to the horizontal gantry member and configured to move along the first horizontal direction; and
a substrate transfer robot coupled to the horizontal driving member and driven in a second horizontal direction perpendicular to the first horizontal direction and a rotation direction,
wherein a first exhaust module is provided in the vertical gantry member, a second exhaust module is provided on the horizontal gantry member, and a third exhaust module is provided on the horizontal driving member, and
wherein the second exhaust module and the third exhaust module are configured to discharge air toward the second horizontal direction.

11. The chamber of claim 10, wherein the first exhaust module is provided at a lower end of the vertical gantry member and discharges air in a direction below a floor surface.

12. The chamber of claim 10, wherein the second exhaust module is provided in a pair, one of which is installed at each end of the horizontal gantry member to exhaust air in the second horizontal direction.

13. The chamber of claim 12, wherein the second exhaust modules each operate independently.

14. The chamber of claim 10, wherein the third exhaust module is installed on a front side of the horizontal driving member facing the second horizontal direction and discharges air in the second horizontal direction.

15. The chamber of claim 10, wherein the first exhaust module, the pair of second exhaust modules, and the third exhaust module each operate independently.

16. The chamber of claim 10, wherein the first exhaust module, the pair of second exhaust modules, and the third exhaust module each include a fan unit that generates airflow for exhausting air and a filter positioned in a direction of exhaust of air by the fan unit.

17. The chamber of claim 10, wherein a negative pressure is formed inside the vertical gantry member, the horizontal gantry member, and the horizontal driving member.

18. The chamber of claim 10, wherein the exhaust fan is positioned opposite the second exhaust module and the third exhaust module.

19. A substrate processing apparatus, comprising:
a load port module configured to have a stand on which a cassette containing a substrate is placed;
an index module configured to have an index robot for transferring a substrate with respect to the cassette;
a transfer module configured to receive a substrate from the index module and transfer the substrate to a process chamber where a process on the substrate is performed; and
a processing module in which one or more process chambers are arranged,
wherein the transfer module comprises:
a vertical gantry member configured to extend in a vertical direction;
a horizontal gantry member coupled to the vertical gantry member to move in the vertical direction and configured to extend along a first horizontal direction perpendicular to the vertical direction;
a horizontal driving member coupled to the horizontal gantry member and configured to move along the first horizontal direction; and
a substrate transfer robot coupled to the horizontal driving member and driven in a second horizontal direction perpendicular to the first horizontal direction and a rotation direction,
wherein a first exhaust module is provided in the vertical gantry member, a second exhaust module is provided on the horizontal gantry member, and a third exhaust module is provided on the horizontal driving member, and
wherein the second exhaust module and the third exhaust module are configured to discharge air toward the second horizontal direction.

20. The apparatus of claim 19, wherein an exhaust fan is positioned opposite the second exhaust module and the third exhaust module on a side wall of a transfer chamber where the transfer module is positioned.
